(19) United States
(12) Patent Application Publication
(10) Pub. No.: US 2024/0012034 A1
(43) Pub. Date: Jan. 11, 2024

(54) Device for Determining a Current Flowing Through a Current Conductor, and an Electrical System having such a Device

(71) Applicant: Robert Bosch GmbH, Stuttgart (DE)

(72) Inventors: Robert Peter Uhlig, Dettingen/Erms (DE); Christian Karcher, Sinzheim (DE); Balazs Bence Harsanyi, Bietigheim-Bissingen (DE)

(21) Appl. No.: 18/252,265

(22) PCT Filed: Oct. 28, 2021
(86) PCT No.: PCT/EP2021/079939

§ 371 Date: May 9, 2023

(30) Foreign Application Priority Data
Nov. 10, 2020 (DE) 10 2020 214 072.3

(51) Int. Cl. G01R 15/20

(52) U.S. Cl. CPC G01R 15/207

(57) ABSTRACT

A device for determining a current flowing through a conductor is disclosed. The device includes a magnetic field sensor unit having at least one first sensor element and a second sensor element, each of which detects a magnetic field strength along a detection direction. The device is designed to determine the current according to the magnetic field strengths detected by way of the first sensor element and the second sensor element. The conductor has a constriction transversely to the longitudinal direction of the conductor, and the magnetic field sensor unit is positioned on the conductor in such a way that the first sensor element is positioned above a first region of the conductor and the second sensor element is positioned above a second region of the conductor, the first region and the second region differing from one another in width due to the constriction. The first sensor element and the second sensor element each use a planar measuring method and each have a detecting device which is parallel to the main extension plane of the conductor, the detecting devices being parallel to one another. An electrical system having such a device is also disclosed.

### PRIOR ART

The invention relates to a device for determining a current flowing through a conductor, said device comprising a magnetic field sensor unit having at least one first sensor element and a second sensor element, each of which detects a magnetic field strength along a detection direction, and said device being designed to determine the current according to the magnetic field strengths detected by means of the first sensor element and the second sensor element.

Corresponding devices for determining the current flowing through a conductor are already known to a person skilled in the art. In these devices, the sensor elements are designed as vertical magnetic field sensors and are positioned on opposite sides of the conductor such that the magnetic field can be detected in the vertical direction with respect to the main extension plane. The magnetic field, which is generated in a circular manner around the conductor due to the current flowing through the conductor, in this case acts on the sensor elements in the opposite directions as a result of their corresponding positioning, for example upward in the case of the first sensor element and downward in the case of the second sensor element. By contrast, external interference fields typically act on the two sensors in the same direction, since these interference fields have a certain homogeneity. These stray fields can then be subtracted out by differential evaluation during the actual determination of the current. The difference quotient is in this case understood to be a gradient of the magnetic field.

### DISCLOSURE OF THE INVENTION

The invention relates to a device for determining a current flowing through a conductor, said device comprising a magnetic field sensor unit having at least one first sensor element and a second sensor element, each of which detects a magnetic field strength along a detection direction, and said device being designed to determine the current according to the magnetic field strengths detected by means of the first sensor element and the second sensor element.

One aspect of the invention consists in that the conductor has a constriction transversely to the longitudinal direction of the conductor, the magnetic field sensor unit being positioned on the conductor such that the first sensor element is offset parallel to the main extension plane of the conductor and is positioned above a first region of the conductor, and the second sensor element is offset parallel to the main extension plane of the conductor and is positioned above a second region of the conductor, the first region and the second region differing from one another in width transversely to the longitudinal direction due to the constriction, and the first sensor element and the second sensor element each using a planar measurement method and each having a detection direction which is parallel to the main extension plane of the conductor, which detection directions are parallel to one another.

It is advantageous in this case that, as a result of the corresponding positioning of the sensor elements and the design of the conductor, the sensor elements can use a planar measuring method in order to allow a differential evaluation of the magnetic field strengths for determining the current. In this case, the conductor, due to its corresponding design, has a higher current density in the region of the constriction than outside the constriction, as a result of which a corresponding magnetic field gradient is formed in the direction of the main extension plane of the conductor, which magnetic field gradient can be detected by the sensor elements by means of the planar measuring method and can be used for determining the current. As a result, external interference fields can be subtracted out when determining the current.

Compared to the vertical measuring method used in the prior art, the planar measurement method also has the advantage of an improved signal-to-noise ratio, increased accuracy, higher sensitivity and a greater fire width.

The conductor can be designed, for example, as an electrical cable or also as a busbar. If the conductor is round or square, the main extension plane can be defined in any way, taking into account the corresponding geometry. In this case, positioned above a region of the conductor means that the sensor element is positioned at the relevant region so as to be perpendicularly spaced apart from the main extension plane.

The current flowing through this conductor generates a magnetic field which forms around the conductor in a substantially circular manner.

Determining the current is in this case understood to mean that the electrical current intensity is determined, which corresponds to the charge flowing through the conductor.

The longitudinal direction is in this case typically understood to mean the direction along which the current substantially flows.

The sensor elements of the magnetic field sensor can be designed, for example, as a Hall sensor, as an AMR sensor, as a GMR sensor or also as a TMR sensor. It is then possible to infer the current flowing through the conductor according to the detected magnetic field strengths, since this flowing current generates a corresponding magnetic field.

Constriction is understood to mean a recess of the conductor transverse to the longitudinal direction of the conductor, which recess reduces the cross-sectional area of the conductor in the longitudinal direction. Such a reduction in the cross-sectional area in turn results in an increase in the current density in this region.

In one embodiment of the invention, the constriction is designed in a stepped manner such that the conductor additionally has at least one further region having a width transverse to the longitudinal direction that differs from that of the first region and the second region.

It is advantageous in this case that the skin effect in the conductor can be reduced. This in turn results in increased frequency stability when determining the current.

In particular, the further region has a greater width than the first and second region, on which the first sensor element and the second sensor element are positioned, respectively.

In a further embodiment of the invention, the constriction is designed such that a ratio between the maximum and the minimum cross-sectional area of the conductor in the longitudinal direction is less than two.

It is advantageous in this case that the heat loss generated due to the higher current density within the constriction is limited.

According to one embodiment of the invention, the constriction is formed from both sides transversely to the longitudinal direction of the conductor.

It is advantageous in this case that a symmetrical design of the conductor is possible, which improves the measurement tolerances of the devices, in particular the positioning of the magnetic field sensor unit.

According to one embodiment of the invention, the constriction is formed from only one side transversely to the longitudinal direction of the conductor.

It is advantageous in this case that such a one-sided recess can be implemented particularly easily in terms of manufacture, as a result of which cost and time expenditure is optimized during manufacture.

According to one embodiment of the invention, the first sensor element and the second sensor element are oriented such that the relevant detection direction of the first sensor element and of the second sensor element extends in parallel with the longitudinal direction of the conductor.

It is advantageous in this case that a particularly large gradient can be achieved in this direction.

According to one embodiment of the invention, the first sensor element and the second sensor element are oriented such that the relevant detection direction of the first sensor element and of the second sensor element extends transversely to the longitudinal direction of the conductor.

It is advantageous in this case for the magnetic field to also extend in this direction.

The invention also relates to an electrical system having a device according to the invention.

Such an electrical system can be, for example, an electric machine, for example a synchronous machine, having an inverter. In this case, the conductor can be designed, for example, as a phase of the inverter, as a result of which the corresponding phase current which flows through this phase can be measured.

### DRAWINGS

FIG. 1 is a perspective view of a device for determining a current flowing through a conductor according to the prior art.

FIG. 2 is a perspective view of a first embodiment of a device according to the invention for determining a current flowing through a conductor.

FIG. 3 is a perspective view of a second embodiment of a device according to the invention for determining a current flowing through a conductor.

### DESCRIPTION OF EMBODIMENTS

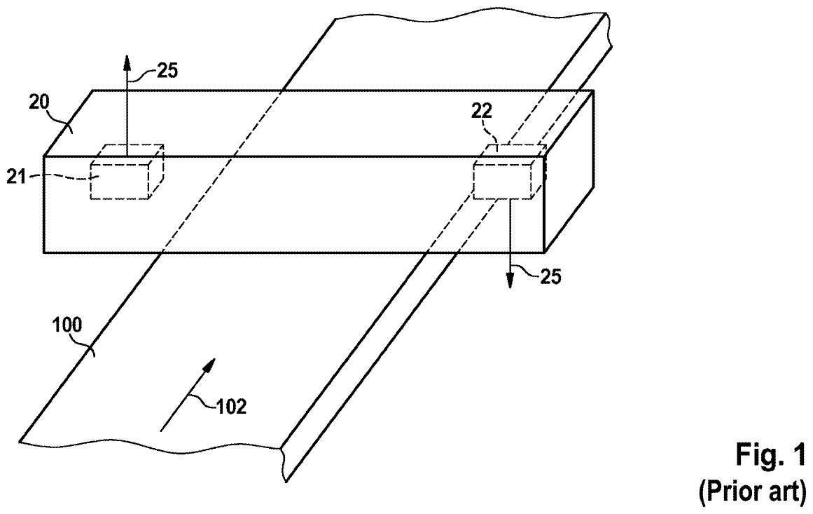

FIG. 1 is a sectional representation of a device for determining a current flowing through a conductor according to the prior art.

A device is shown. The device comprises a magnetic field sensor unit 20 which is positioned on a conductor 100. The magnetic field sensor unit 20 in turn comprises at least one first sensor element 21 and a second sensor element 22, each of which detects a magnetic field strength along a detection direction 25.

Here, the magnetic field sensor unit 20 is positioned on a conductor 100 such that the first sensor element 21 and the second sensor element 22 are positioned laterally above the main extension plane of the conductor 100 on opposite sides of the conductor 100 and each have a detection direction 25 which is vertical with respect to the main extension plane. The first sensor element 21 and the second sensor element 22 correspondingly use a vertical measurement method.

If a current flows in the longitudinal direction 102 through the conductor 100, it generates a magnetic field, the corresponding magnetic field strength being directed upward in the first sensor element 21 and downward in the second sensor element 22.

The device is designed to detect a magnetic field strength in each case by means of the first sensor element 21 and the second sensor element 22 and to determine the current which flows through the conductor 100 according to the magnetic field strengths detected by means of the first sensor element 21 and the second sensor element 22.

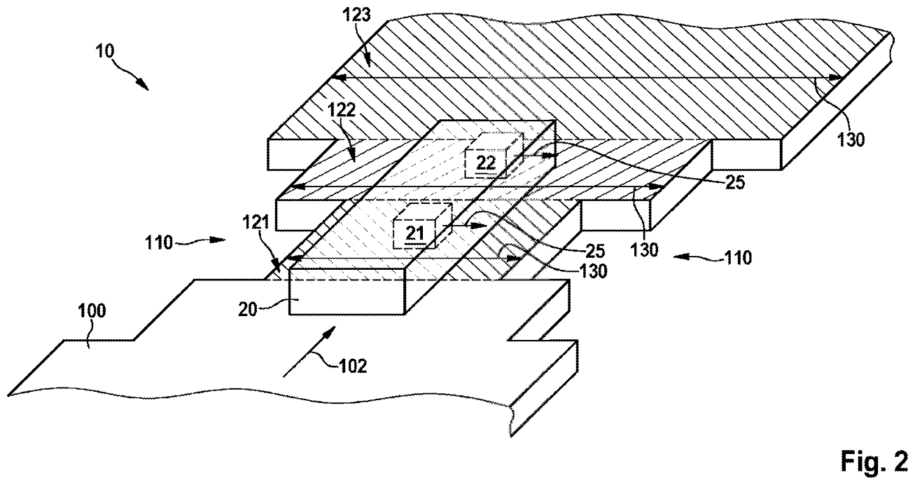

FIG. 2 is a perspective view of a first embodiment of a device according to the invention for determining a current flowing through a conductor.

A device 10 is shown for determining a current flowing through a conductor 100, which device differs from the device according to FIG. 1 in that the conductor 100 has a constriction 110 transversely to the longitudinal direction 102 of the conductor 100. The constriction 110 is in this case formed from both sides transversely to the longitudinal direction 102 of the conductor 100.

In addition, in contrast to the device according to FIG. 1, in the case of the device the magnetic field sensor unit 20 is positioned on the conductor 100 such that the first sensor element 21 is offset parallel to the main extension plane of the conductor 100 and is positioned above a first region 121 of the conductor 100, and the second sensor element 22 is offset parallel to the main extension plane of the conductor and is positioned above a second region 122 of the conductor 100, the first region 121 and the second region 122 differing from one another in width 130 transversely to the longitudinal direction 102 due to the constriction 110. Furthermore, the first sensor element 21 and the second sensor element 22 each use a planar measurement method and each have a detection direction 25 which is parallel to the main extension plane of the conductor 100, which detection directions are parallel to one another. In this case, the first sensor element 21 and the second sensor element 22 are oriented such that the relevant detection direction 25 of the first sensor element 21 and of the second sensor element 22 extends transversely to the longitudinal direction 102 of the conductor 100, with the magnetic field also extending in this direction, which magnetic field is formed by a current flowing in the longitudinal direction 102 and has a corresponding gradient due to the constriction 100 with the current density changed thereby within the conductor 100.

The constriction 110 is designed in a stepped manner such that the conductor 100 additionally has at least one further region 123 having a width 130 transverse to the longitudinal direction 102 that differs from that of the first region 121 and the second region 122.

Furthermore, the constriction 110 is designed such that a ratio between the maximum and the minimum cross-sectional area of the conductor 100 in the longitudinal direction 102 is less than two, i.e., the cross-sectional area of the conductor 100 is at most halved due to the constriction 110.

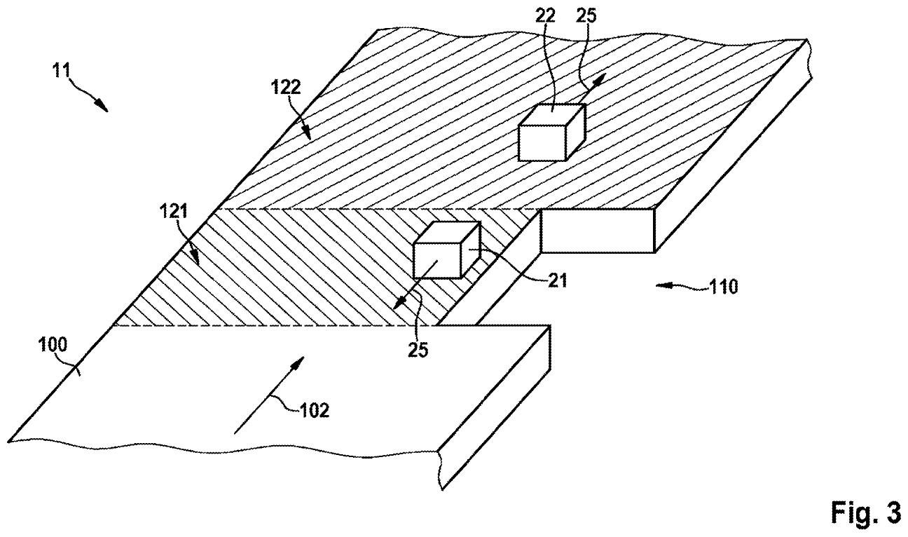

FIG. 3 is a perspective view of a second embodiment of a device according to the invention for determining a current flowing through a conductor.

A device 11 is shown for determining a current flowing through a conductor 100, the device 11 differing from the device 10 according to FIG. 2 in that the constriction 110 is formed from only one side transversely to the longitudinal direction 102 of the conductor 100 and is additionally designed with only one step, so that only a first region 121 and a second region 122 having mutually different widths 130 are formed, on which the first sensor element 21 and the second sensor element 22 are positioned, respectively.

A further difference from the device 10 is that in the case of the device 11, the first sensor element 21 and the second sensor element 22 are oriented such that the relevant detection direction 25 of the first sensor element 21 and of the second sensor element 22 extends in parallel with the longitudinal direction 102 of the conductor 100, in which detection direction a gradient field can also be detected due to the constriction and the corresponding current flow.

1. A device for determining a current flowing through a conductor, comprising a magnetic field sensor unit having at least one first sensor element and a second sensor element, each of which detects a magnetic field strength along a detection direction, wherein:
the device being is designed to determine the current according to the magnetic field strengths detected by way of the at least one first sensor element and the second sensor element,
the conductor has a constriction transversely to the longitudinal direction of the conductor,
the magnetic field sensor unit is positioned on the conductor such that the first sensor element is offset parallel to the main extension plane of the conductor and is positioned above a first region of the conductor, and the second sensor element is offset parallel to the main extension plane of the conductor and is positioned above a second region of the conductor, the first region and the second region differing from one another in width transversely to the longitudinal direction due to the constriction, and
the at least one first sensor element and the second sensor element are each configured to use a planar measurement method and each have a detection direction which is parallel to the main extension plane of the conductor, which detection directions are parallel to one another.

2. The device according to claim 1, wherein the constriction is designed in a stepped manner such that the conductor additionally has at least one further region having a width transverse to the longitudinal direction that differs from that of the first region and the second region.

3. The device according to claim 1, that wherein the constriction is designed such that a ratio between the maximum and the minimum cross-sectional area of the conductor in the longitudinal direction is less than two.

4. The device according to claim 1, wherein the constriction is formed from both sides transversely to the longitudinal direction of the conductor.

5. The device according to claim 1, wherein the constriction is formed from only one side transversely to the longitudinal direction of the conductor.

6. The device according to claim 5, wherein the at least one first sensor element and the second sensor element are oriented such that the relevant detection direction of the at least one first sensor element and of the second sensor element extends in parallel with the longitudinal direction of the conductor.

7. The device according to claim 1, wherein the at least one first sensor element and the second sensor element are oriented such that the relevant detection direction of the at least one first sensor element and of the second sensor element extends transversely to the longitudinal direction of the conductor.

8. An electrical system comprising a device according to claim 1.
